(19) United States
(12) Patent Application Publication
(10) Pub. No.: US 2002/0106587 A1
(43) Pub. Date: Aug. 8, 2002

(54) Two mask via pattern to improve pattern definition

(75) Inventors: Todd Lukanc, San Jose, CA (US); Christopher F. Lyons, San Jose, CA (US)

Correspondence Address: Foley & Lardner, Suite 500, 3000 K Street, N.W., Washington, DC, 20007-8696, US

(73) Assignee: ADVANCED MICRO DEVICES, INC.

(21) Appl. No.: 09/790,537

(22) Filed: Feb. 23, 2001

Related U.S. Application Data
(63) Continuation-in-part of application No. 09/716,218, filed on Nov. 21, 2000.

(51) Int. Cl. G03F 7/00

(52) U.S. Cl. 430/312; 430/314; 430/394

(57) ABSTRACT

There is provided a method of making plurality of vias in a first layer using two different masks. A first photoresist layer is formed over the first layer and exposed layer through a first mask. A first opening is formed in the first photoresist layer, and a first via is formed in the first layer through the first opening. Then, a different, second photoresist layer is exposed through a second mask different from the first mask. A second opening is formed in this photoresist layer and a second via is formed in the first layer through the second opening.

This application is a continuation-in-part of U.S. application Ser. No. 09/716,218 filed on Nov. 21, 2000, which is incorporated herein by reference in its entirety.

### BACKGROUND OF THE INVENTION

This invention is related generally a method of making a semiconductor device and specifically to photolithographically forming plural vias in an insulating layer by using a different masks.

Semiconductor devices having smaller and smaller features are approaching a limit in which such features may be formed by conventional photolithography methods. For example, conventional photolithography methods produce vias with a large distance between the vias, as illustrated in FIGS. 1A and 1B. A positive photoresist layer 3 is formed over a layer 1 in which it is desired to form a first and second via. A first region 5 and a second region 7 in the photoresist layer 3 are simultaneously exposed to actinic light 8 through openings 11 and 13 in a single mask or reticle 9, as illustrated in FIG. 1A. The terms mask and reticle are used interchangeably, with the term reticle often applied to a mask used in step and repeat exposure systems. The exposed regions 5 and 7 are then developed and removed, while an unexposed region 6 remains. A gas or liquid etching medium is then supplied through the openings 5, 7 in the photoresist layer 3 to etch vias 15, 17 in layer 1, as illustrated in FIG. 1B. The vias 15, 17 are usually formed in rows and columns when viewed from the top, as illustrated in FIG. 1C.

However, this prior art method cannot form vias with a high enough density. As illustrated in FIGS. 1B and 1C, the intervia spacing 19 (i.e., the minimum distance between the edges of the adjacent vias 15 and 17 which is covered by photoresist region 6 during etching) cannot be made smaller than 0.24 microns using 248 nm incident radiation because of diffraction and mask fabrications problems (i.e., the minimum reproducible spacing 19 is about equal to the wavelength of incident radiation). The reproducible intervia spacing 19 can be reduced to about 0.18 microns by using a shorter wavelength of incident radiation or phase shifting methods. Thus, the minimum reproducible intervia spacing 19 between adjacent vias 15 and 17 cannot be made small enough to achieve the desired density.

For example, actinic light 8 passing through openings 11 and 13 in an opaque region in mask 9, spreads laterally due to diffraction effects. Thus, if the openings 11 and 13 are placed sufficiently close, the laterally diffracted light will expose all or a large portion of photoresist region 6. If all of photoresist region 6 is exposed and removed, then only one large via will be formed in layer 1, as illustrated in FIG. 2A. Alternatively, if a large portion of region 6 is exposed as illustrated in FIG. 2B, then the intervia spacing 19 will too thin, and thus unstable and collapsible during subsequent processing small (i.e., a non-reproducibly small intervia spacing results). When the intervia spacing is too small as illustrated in FIG. 2B, it also becomes difficult to inspect the in-process wafer with an automatic inspection apparatus, such as a scanning electron microscope. The cross sectional via shape may also become oval rather than rectangular if the intervia spacing 19 unreproducibly small. The oval shape negatively impacts the ability to fill the vias with metal electrodes and interconnects.

Furthermore, it is difficult to precisely fabricate a mask or reticle 9 having a very small opaque region 14 between openings 11 and 13. Therefore, the intervia spacing 19 in layer 1 cannot be made small enough to form a high enough density of vias 15, 17 due to diffraction and mask fabrication constraints in the prior art method of FIGS. 1A and 1B.

A similar problem occurs with the use of a negative photoresist. A negative photoresist differs from a positive photoresist in that the exposed areas are rendered insoluble to developer. When the to be formed via width is very narrow, the opaque regions 14 on a mask or reticle 9 have to also be made very narrow. Therefore, the diffraction effect causes the exposing light 8 to spread laterally and expose the regions 5, 7 of the negative photoresist layer 3, as illustrated in FIG. 2C. Thus, all or part of regions 5 and 7 are rendered insoluble and are not removed by the developer. For example, in FIG. 2C a part of region 5 is rendered insoluble and all of region 7 is rendered insoluble. Since regions 5 and 7 are rendered either partially or completely insoluble, vias either cannot be formed in desired locations (17) in layer 1 or the via width is much lower than desired (such as via 15), as illustrated in FIG. 2D. Furthermore, it is difficult to precisely fabricate a mask 9 having a very small opaque regions 14 corresponding to the vias 15, 17 in layer 1. Therefore, the vias 15, 17 having a desired size or width are not achieved due to diffraction and mask fabrication constraints in the prior art method.

### BRIEF SUMMARY OF THE INVENTION

According to one aspect of the present invention, there is provided a method of making plurality of vias in a first layer, comprising forming a first photoresist layer over the first layer, exposing the first photoresist layer through a first mask, forming a first opening in the first photoresist layer, forming a first via in the first layer through the first opening in the first photoresist layer, forming a second photoresist layer, different from the first photoresist layer, over the first layer, exposing the second photoresist layer through a second mask different from the first mask, forming a second opening in the second photoresist layer, and forming a second via in the first layer through the second opening in the second photoresist layer.

According to another aspect of the present invention, there is provided a method of making plurality of vias in a first layer, comprising forming a first photoresist layer over an hard mask layer which is located above the first layer, exposing the first photoresist layer through a first mask, forming a first opening in the first photoresist layer, forming a first opening in the hard mask layer through the first opening in the first photoresist layer, forming a second photoresist layer, different from the first photoresist layer, over the hard mask layer, exposing the second photoresist layer through a second mask different from the first mask, forming a second opening in the second photoresist layer, forming a second opening in the hard mask layer through the second opening in the second photoresist layer, and forming a first via and a second via in the first layer using the hard mask layer as a mask.

According to another aspect of the present invention, there is provided a semiconductor device, comprising an active element on a substrate, an insulating layer over the active element, a first via and a second via in the insulating layer which are separated by a distance of 0.17 microns or less, and a conductive material in the first and second vias.

### BRIEF DESCRIPTION OF THE DRAWINGS

FIGS. 1A and 1B are side cross sectional views of a prior art method of making vias.

FIG. 1C is a top view of an in-process semiconductor device containing vias made by the prior art method of FIGS. 1A and 1B.

FIGS. 2A, 2B, 2C and 2D illustrate side cross sectional views of problems that occur in the prior art methods.

FIGS. 3A, 3B, 3C, 3D and 3E are side cross sectional views of a method of making vias according to a first preferred embodiment of the present invention.

FIGS. 4A, 4B, 4C, 4D and 4E are side cross sectional views of a method of making vias according to a second preferred embodiment of the present invention.

FIGS. 5A, 5B, 5C, 5D and 5E are side cross sectional views of a method of making vias according to a third preferred embodiment of the present invention.

FIGS. 6 and 7 are top views of an in-process semiconductor device containing vias made by the method of the preferred embodiments of the present invention.

FIG. 8 is a partial side cross sectional view of a completed semiconductor device made by the method of the preferred embodiments of the present invention.

### DETAILED DESCRIPTION OF THE INVENTION

The present inventors have realized that via density may be increased and the intervia spacing may be reduced if adjacent regions are exposed in separate photoresist layers through separate masks or reticles. By using separate masks to expose photoresist regions used to form adjacent vias, the diffraction and mask fabrication constraints of the single mask prior art method may be reduced or eliminated. The benefit of the two separate exposures is to eliminate the potential interactions of the radiation (i.e., visible light or UV radiation) through small openings very close together. Since the radiation in the openings of the same mask has the same “phase” the interactions will be doubled. By exposing the adjacent regions separately, the level of radiation interaction is reduced to the sensitivity threshold of the photoresist material.

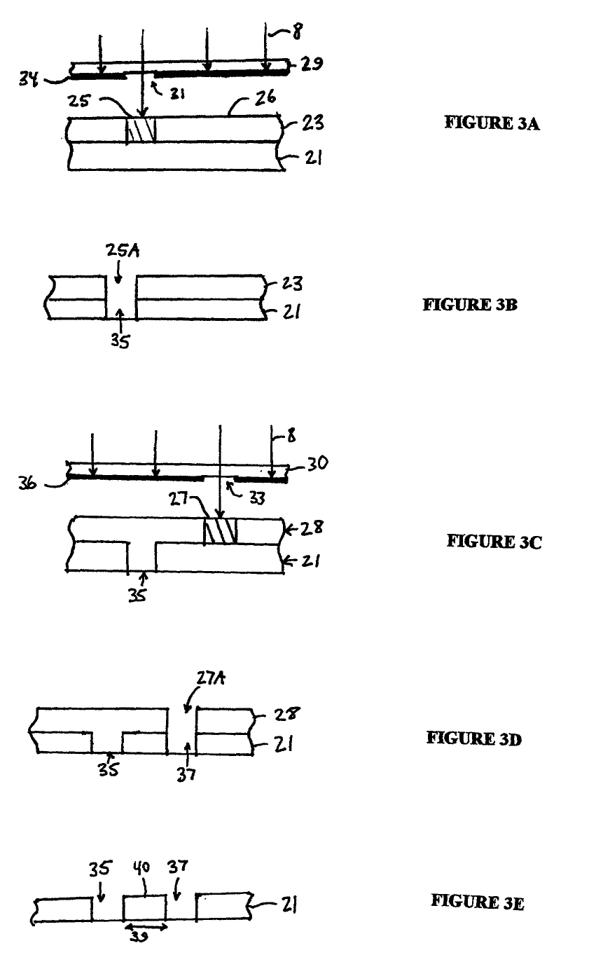

FIGS. 3A-3E illustrate a method of forming vias using two positive photoresist layers according to a first preferred embodiment of the present invention. A positive first photoresist layer 23 is formed over the first layer 21. The first photoresist layer 23 is then exposed to radiation, such as actinic light or other suitable UV radiation, through opening 31 in a first mask or reticle 29 to form a first exposed region 25 in the photoresist layer 23, as illustrated in FIG. 3A. The exposed region 25 of the first photoresist layer 23 is rendered soluble to developer. Other regions of the first photoresist layer 23 are shielded by the opaque layer 34 of the mask 29 and are not exposed.

After exposing region 25, the first photoresist layer 23 is developed (i.e., exposed to a developer fluid) to remove the exposed, soluble photoresist from region 25 to provide a first opening 25A to layer 21. Unexposed photoresist region 26 is not removed during development, and is used as a mask for subsequent etching of layer 21.

After the opening 25A is provided in the first photoresist layer 23, a first via 35 is formed in layer 21 by providing an etching gas or an etching liquid to the first layer through the first opening 25A in the first photoresist layer 23, as shown in FIG. 3B. After completion of the etching, the remaining first photoresist layer 23 is removed by conventional removal techniques, such as ashing.

A different, second positive photoresist layer 28 is then formed over the first layer 21. The second photoresist layer 28 fills the first via 35 in layer 21. The second photoresist layer 28 is then exposed to radiation through opening 33 in a second mask or reticle 30, different from the first mask 29, to form a second exposed region 27 in the photoresist layer 28, as illustrated in FIG. 3C. The other regions of the photoresist layer 28 are not exposed because they are shielded by an opaque region 36 of the second mask 30.

After exposing region 27, the second photoresist layer 28 is developed (i.e., exposed to a developer fluid) to remove the exposed, soluble photoresist from region 27 to provide a second opening 27A to layer 21. Unexposed regions of photoresist layer 28 are not removed during development, and are used as a mask for subsequent etching of layer 21.

After the second opening 27A is provided in the second photoresist layer 28, the second via 37 is formed in layer 21 by providing an etching gas or an etching liquid to the first layer through the second opening 27A in the second photoresist layer 28, as shown in FIG. 3D. After completion of the etching, the remaining second photoresist layer 28 is removed by conventional removal techniques, such as ashing.

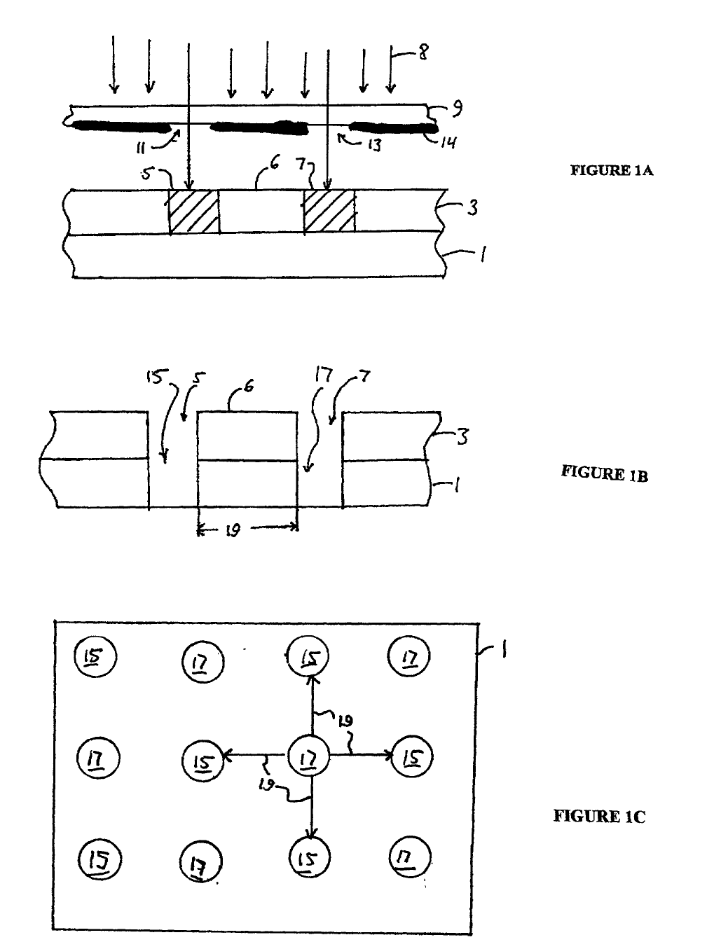

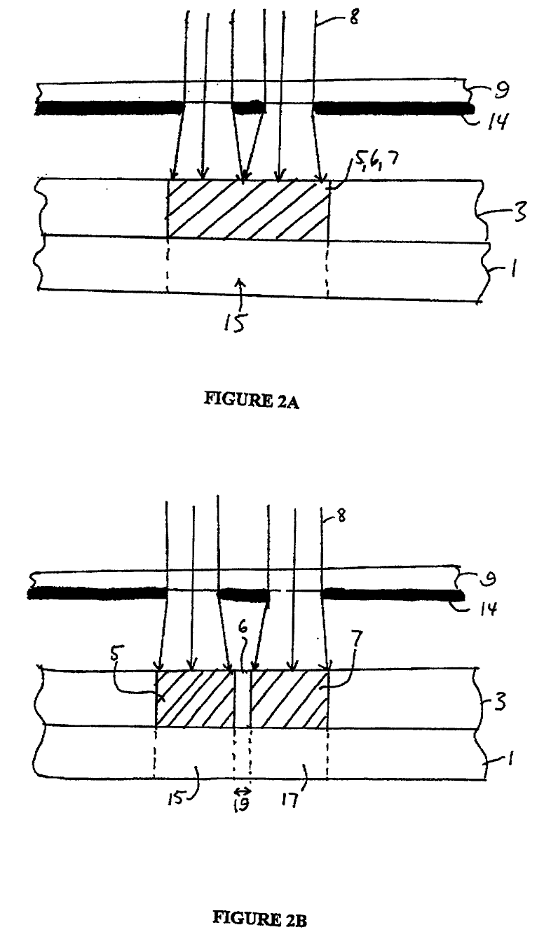

The first 35 and second 37 vias separated by an intervia region 40 are formed in layer 21, as illustrated in FIG. 3E. Thus, the intervia distance 39 that separates the first via 35 and the second via 37 (i.e., the intervia region 40 length) is smaller than a distance 19 that may be reproducibly achieved by the prior art method illustrated in FIG. 1B. For example, the reproducible intervia distance 39 may be 0.17 microns or less, preferably between about 0.07 microns and 0.12 microns, most preferably between about 0.07 and 0.08 microns. The distance 39 is obtained as follows. Assuming that a minimum distance between tops of via edges is at least 0.01 microns, a deviation from the desired via width is about 0.01 to 0.02 microns (i.e., the via diameter exceeds the desired diameter by about 10%—or 0.01 to 0.02 microns for current technologies) and the alignment capability between the masks is about 0.04 to 0.05 microns for current technologies, results in a minimum reproducible intervia distance 39 of about 0.07 to about 0.08 microns. Preferably, the intervia distance 39 is less than the wavelength of the exposing radiation but is equal to or greater than about ½ of the wavelength of the exposing radiation. Thus, by forming the first and the second via using different masks instead of the same mask, a higher via density may be achieved.

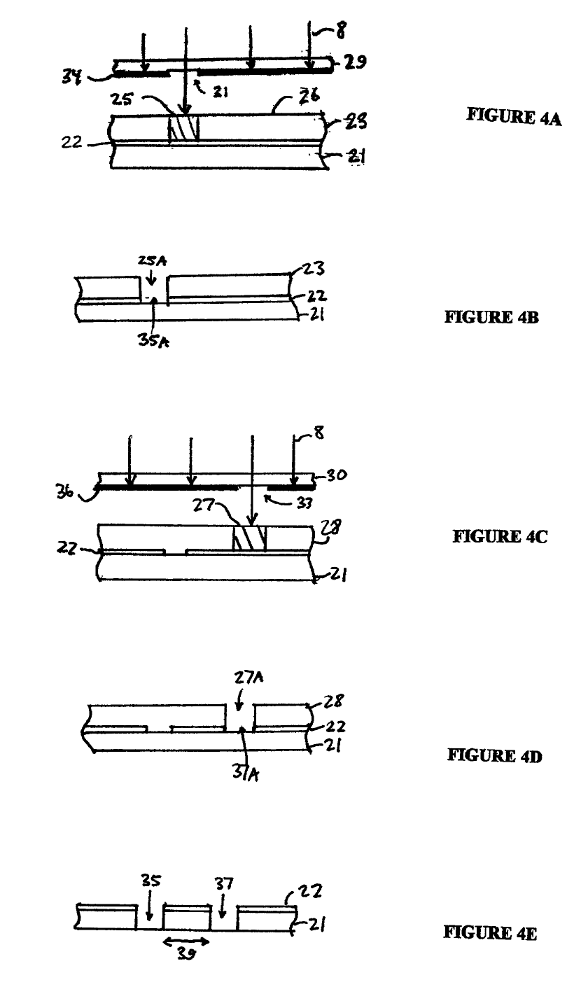

FIGS. 4A-4E illustrate a method of forming vias using two positive photoresist layers and an hard mask layer according to a second preferred embodiment of the present invention. The second embodiment is similar to the first embodiment, except that an hard mask layer 22 is used to avoid the introduction of the second photoresist layer 28 into the first via 35. The method of the second embodiment is advantageous because it avoids a possibility that the photoresist layer 28 will get stuck and will not removed from the deep via 35, and because it also avoids a possibility that the photoresist layer 28 does not fully cover the deep first via 35 while the second via 37 is being etched.

A thin hard mask layer 22 is formed over the first layer 21. The hard mask layer 22 may be any layer that has a higher etch resistance than the first layer to the gas or liquid that is used to etch the first layer 21. For example, the hard mask layer 22 may be an insulating layer, such as silicon nitride, silicon oxynitride, aluminum oxide or tantalum oxide when the first layer is silicon oxide, spin-on glass, PSG, BPSG or a polymer layer, such as a siloxane or silsesquioxane (i.e., hydrogen silsesquioxane or “HSQ”). The hard mask layer 22 may also comprise a metal, such as aluminum or titanium, or a metal containing layer, such as titanium nitride, if the hard mask layer 22 is a temporary layer that is removed after forming the vias. Preferably, the hard mask layer 22 is thinner than the first layer 21. For example, the hard mask layer thickness may be 1-30%, preferably 2-20%, most preferably 3-10% of the thickness of the first layer 21.

A positive first photoresist layer 23 is formed over the first layer 21 and the hard mask layer 22. The first photoresist layer 23 is then exposed to radiation, such as actinic light or other suitable UV radiation, through opening 31 in a first mask or reticle 29 to form a first exposed region 25 in the photoresist layer 23, as illustrated in FIG. 4A. The exposed region 25 of the first photoresist layer 23 is rendered soluble to developer. Other regions of the first photoresist layer 23 are shielded by the opaque layer 34 of the mask 29 and are not exposed.

After exposing region 25, the first photoresist layer 23 is developed (i.e., exposed to a developer fluid) to remove the exposed, soluble photoresist from region 25 to provide a first opening 25A to the hard mask layer 22. Unexposed photoresist region 26 is not removed during development, and is used as a mask for subsequent etching of layer 22.

After the opening 25A is provided in the first photoresist layer 23, a first opening 35A is formed in the hard mask layer 22 by providing a first etching gas or an etching liquid to the first layer through the first opening 25A in the first photoresist layer 23, as shown in FIG. 4B. The first etching gas or liquid is selected such that it etches the material of layer 22 at a relatively high etching rate.

Preferably, the opening 35A only extends through the hard mask layer 22 while extending into the first layer 21 only to a small amount (such as less than 10% of the thickness of layer 21) or opening 35A does not extend into layer 21 at all. This may be accomplished by selecting the first layer 21 material that has a higher etching resistance to the first etching gas or liquid than the hard mask layer 22 material. Alternatively, layer 21 may have the same as or lower resistance to the first etching gas or liquid, and the etching of the first opening 35 is timed to stop when the first layer 21 is reached. Furthermore, if desired, the first layer 21 may contain several sublayers, one of which may be an optional etch stop sublayer which has a high etching resistance to the first etching gas or liquid. Thus, the opening 35A would then extend to the etch stop sublayer. After completion of the etching, the remaining first photoresist layer 23 is removed by conventional removal techniques, such as ashing.

A different, second positive photoresist layer 28 is then formed over the hard mask layer 22. The second photoresist layer 28 fills the relatively shallow first opening 35A in layer 22. The second photoresist layer 28 is then exposed to radiation through opening 33 in a second mask or reticle 30, different from the first mask 29, to form a second exposed region 27 in the photoresist layer 28, as illustrated in FIG. 4C. The other regions of the photoresist layer 28 are not exposed because they are shielded by an opaque region 36 of the second mask 30.

After exposing region 27, the second photoresist layer 28 is developed (i.e., exposed to a developer fluid) to remove the exposed, soluble photoresist from region 27 to provide a second opening 27A to layer 22. Unexposed regions of photoresist layer 28 are not removed during development, and are used as a mask for subsequent etching of layer 22.

After the second opening 27A is provided in the second photoresist layer 28, the second opening 37A is formed in the hard mask layer 22 by providing the first etching gas or an etching liquid to the hard mask layer 22 through the second opening 27A in the second photoresist layer 28, as shown in FIG. 4D. Preferably, the opening 37A only extends through the hard mask layer 22 while extending into the first layer 21 only to a small amount (such as less than 10% of the thickness of layer 21) or opening 37A does not extend into layer 21 at all. After completion of the etching, the remaining second photoresist layer 28 is removed by conventional removal techniques, such as ashing. Since the first opening 35A is relatively shallow, the second photoresist layer 28 is easily removed from this opening.

After the second photoresist layer 28 is removed, vias 35 and 37 are etched in the first layer 21 using the hard mask layer 22 as a mask, as illustrated in FIG. 4E. The vias 35 and 37 may be formed by providing a second etching gas or liquid through the openings 35A and 37A in the hard mask layer 22. The second etching gas or liquid is selected such that it etches the first layer 21 at a higher etching rate than the hard mask layer 22. Preferably, the second etching gas or liquid substantially does not etch the hard mask layer 22. The hard mask layer 22 may be left on layer 21 and incorporated into the semiconductor device or removed after forming the vias 35 and 37 (i.e., a metal hard mask layer is preferably removed).

Thus, the first 35 and second 37 vias, separated by an intervia region 40 having a length 39, are formed in layer 21, as illustrated in FIG. 4E. Therefore, the same via spacing (i.e., intervia distance) 39 may be achieved by using two photoresist layers and an hard mask layer according to the method of the second preferred embodiment, as with using the method of the first preferred embodiment.

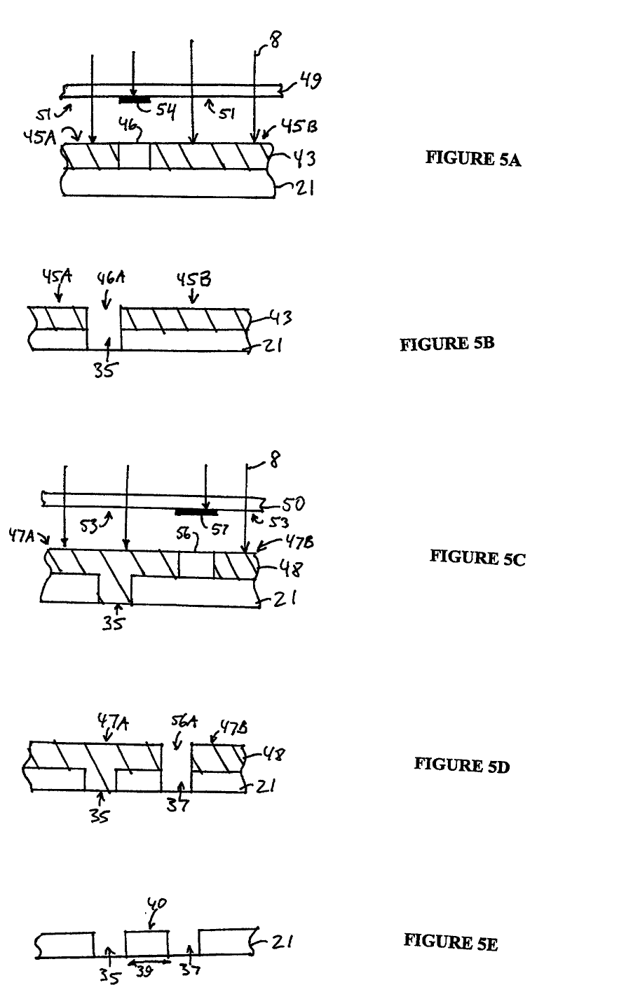

FIGS. 5A-5E illustrate a method of forming vias using two negative photoresist layers according to a third preferred embodiment of the present invention. A negative first photoresist layer 43 is formed over the first layer 21. The photoresist layer 43 is uncrosslinked and is thus developer soluble. The first photoresist layer 43 is then exposed to radiation, such as actinic light or other suitable UV radiation, through openings 51 in a first mask or reticle 49 to form first exposed regions 45A and 45B in the photoresist layer 23, as illustrated in FIG. 5A. The exposure to radiation crosslinks the photoresist in regions 45A and 45B, rendering regions 45A, 45B insoluble to developer. Region 46 of the first photoresist layer 43 is shielded by the opaque layer 54 of the mask 49 and is not exposed.

After exposing regions 45A and 45B, the first photoresist layer 43 is developed (i.e., exposed to a developer fluid) to remove the unexposed, soluble photoresist from region 46 to provide a first opening 46A to layer 21. Exposed photoresist regions 45A and 45B are not removed during development, and are used as a mask for subsequent etching of layer 21.

After the opening 46A is provided in the first photoresist layer 43, a first via 35 is formed in layer 21 by providing an etching gas or an etching liquid to the first layer through the first opening 46A in the first photoresist layer 43, as shown in FIG. 5B. After completion of the etching, the remaining first photoresist layer 43 is removed by conventional removal techniques, such as ashing.

A different, second negative photoresist layer 48 is then formed over the first layer 21. The second photoresist layer 48 fills the first via 35 in layer 21. The second photoresist layer 48 is then exposed to radiation through openings 53 in a second mask or reticle 50, different from the first mask 49, to form second exposed regions 47A and 47B in the photoresist layer 48, as illustrated in FIG. 5C. The region 56 of the photoresist layer 48 is not exposed because it is shielded by an opaque region 57 of the second mask 50.

After exposing regions 47A and 47B, the second photoresist layer 48 is developed (i.e., exposed to a developer fluid) to remove the unexposed, soluble photoresist from region 56 to provide a second opening 56A to layer 21. Exposed regions 47A and 47B of photoresist layer 48 are not removed during development, and are used as a mask for subsequent etching of layer 21.

After the second opening 56A is provided in the second photoresist layer 48, the second via 37 is formed in layer 21 by providing an etching gas or an etching liquid to the first layer through the second opening 56A in the second photoresist layer 48, as shown in FIG. 5D. After completion of the etching, the remaining second photoresist layer 48 is removed by conventional removal techniques, such as ashing.

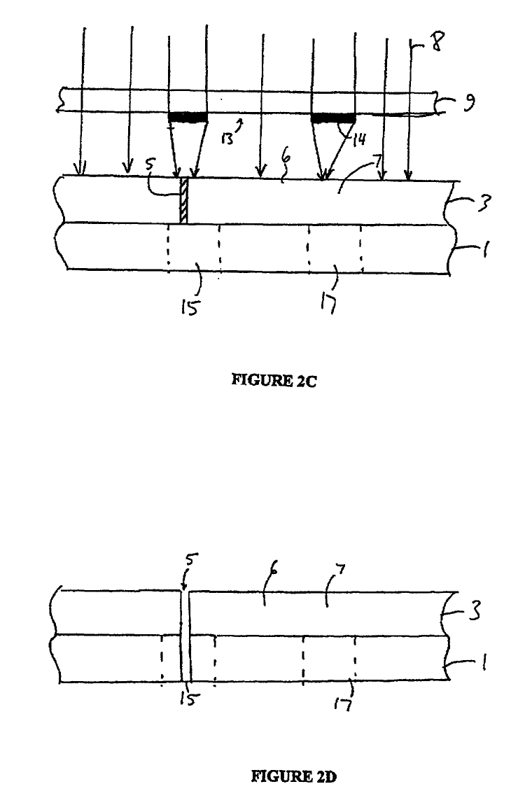

Thus, the first 35 and second 37 vias, separated by an intervia region 40 having a length 39, are formed in layer 21, as illustrated in FIG. 5E. Therefore, the same via spacing (i.e., intervia distance) 39 may be achieved by using negative photoresist layers according to the method of the third preferred embodiment, as with using positive photoresist layers according to the method of the first preferred embodiment. Thus, a higher via density may be achieved by forming the first and the second via using different masks instead of the same mask. Furthermore, unlike the prior art method illustrated in FIGS. 2C and 2D, the method illustrated in FIGS. 5A-E provides vias having a desired width and location.

It should be noted that the hard mask layer 22 of the second preferred embodiment may be used with the negative photoresist layers 43 and 48 of the third preferred embodiment. In this case, rather than forming vias 35 and 37 through the openings 46A and 56A in the photoresist layers 43, 48, openings are formed in the thin hard mask layer 22 by providing the first etching gas or liquid through the photoresist layer openings. The vias 35 and 37 may then be formed in the first layer 21 after removing the second photoresist layer 48 by using the hard mask layer 22 as a mask while providing the second etching gas or liquid through the openings in the hard mask layer.

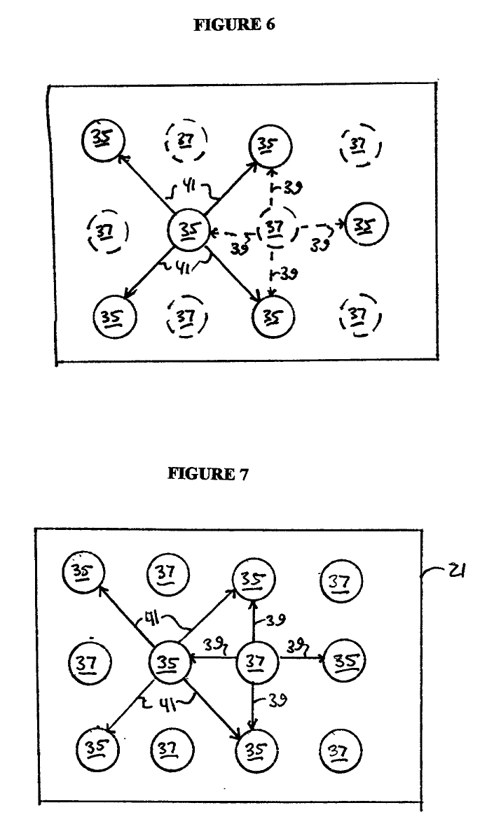

While FIGS. 3A-3E, 4A-4E, 5A-5E illustrate only two vias for ease of explanation, it should be understood that a semiconductor device contains a plurality of vias. FIGS. 6 and 7 illustrate a top view of layer 21 in which a plurality of vias have been formed by the method of the first, second or third preferred embodiments. FIG. 6 illustrates layer 21 at a stage in fabrication of a semiconductor device after the first set of vias 35 have been formed using the first mask, but before the second set of vias 37 have been formed using the second mask. The future location of the vias 37 of the second set are shown by the dashed lines. FIG. 7 illustrates layer 21 at a stage in fabrication of a semiconductor device after both sets of vias 35, 37 have been formed and after the photoresist layer(s) have been removed but before material is deposited into the vias 35, 37.

As shown in FIG. 6, the vias 35 of the first set are preferably arranged in a checkerboard pattern (i.e., a square matrix where vias 35 only occupy the odd/odd and even/even numbered row/column slots or where the vias 35 only occupy the odd/even and even/odd numbered row/column slots). Therefore, the closest distance 41 between adjacent vias 35 of the same set formed using the same mask (i.e., 29) is a diagonal line. In contrast, the closest distance 19 between adjacent prior art vias 15, 17 of the same set formed using the same mask 9 is a vertical or horizontal line. Therefore, by using separate masks to form two sets of vias, the distance between adjacent vias formed using the same mask is increased. For example, a vertical or horizontal line 19 (having an arbitrary length of “y”) between cells of a square matrix of FIG. 1C is shorter than a diagonal line 41 (having a length of 2y/√2+2*[{2r/√2}−r], where “r” is the via radius) between the cells of a square matrix of FIG. 6. Since the adjacent vias 35 formed using the same mask (i.e., 29) are spaced farther apart than in the prior art method, the potential interactions of the radiation through adjacent small mask openings (i.e., 33) is reduced or eliminated.

For example, any via 35 of the first set, having a radius of 90 nm and a minimum intervia distance 39 from an adjacent via 37 of the second set of 180 nm, has a minimum diagonal distance 41 to an adjacent via 35 of the first set of 180*1.414+2*((1.414*90)−90)=329.12 nm. Therefore, by using two masks to pattern adjacent vias 35, 37, the closest distance 41 between adjacent vias 35 of the same set formed using the same mask 29 is increased from 180 nm to 329.12 nm, thus reducing the undesirable radiation interactions through adjacent mask openings 33 and the undesirable results illustrated in FIGS. 2A-D.

In FIG. 7, a first set of a plurality of vias 35 is formed in layer 21 using the first mask 29 or 49, while a second set of a plurality of vias 37 is formed in layer 21 using the second mask 30 or 50. Thus, a via 35 from the first set is located between or adjacent to at least two vias 37 from the second set. Conversely, a via 37 from the second set is located between or adjacent to at least two vias 35 from the first set. It should be noted that the four exemplary vias from one set in the corners of FIG. 7 are located adjacent to only two vias from the other set.

For example, in FIG. 7, an exemplary via 37 in row two, column three, from one set is located between four vias 35 from the other set. Thus, there are two horizontal and two vertical intervia distances 39 between the via of one set and the adjacent vias of the other set. Thus, the vias of the first set 35 and the vias of the second set 37 are separated by a reproducible distance 39 that is smaller than a reproducible distance 19 that may be achieved by the prior art method illustrated in FIG. 1C. Of course, other via configurations than that illustrated in FIG. 7 are possible depending on the required layout of the device, and the layout of the vias 35, 37 is not limited to a square matrix.

The layer 21 containing the vias may comprise any layer used in an electronic or semiconductor device, such as an insulating, metal or semiconductor layer. Preferably, layer 21 comprises an insulating layer in a semiconductor device, such as a first level insulating layer or an intermetal dielectric.

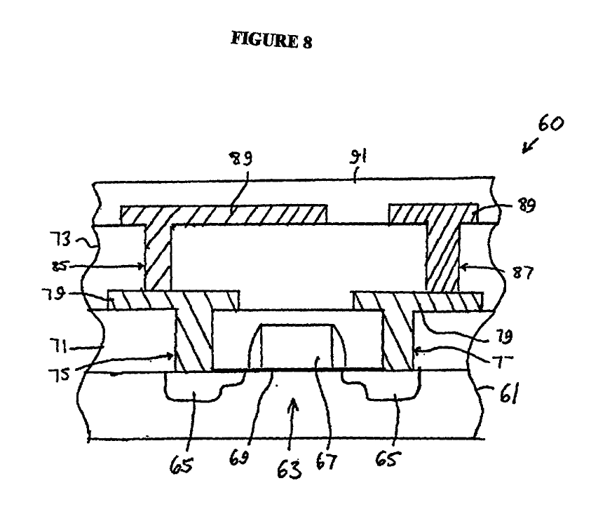

FIG. 8 illustrates a completed semiconductor device 60 containing the vias made by the methods of the first or second preferred embodiment. The semiconductor device 60 contains a substrate 61, which may be a semiconductor (such as silicon or gallium arsenide, etc.), a glass or a plastic material. One or more active elements 63 are formed on the substrate 61. The active element may comprise at least one of a MOSFET, a MESFET, a bipolar transistor, a capacitor, a resistor or any other desired device. For example, FIG. 8 illustrates a MOSFET 63.

The MOSFET 63 contains doped source and drain regions 65 in the substrate 61, a gate electrode 67 with sidewall spacers and a gate dielectric 69 between the gate electrode and the channel region in the substrate 61. At least one insulating layer overlies the active element 63. For example, the at least one insulating layer includes a first level insulating layer 71 and a first intermetal dielectric 73, as illustrated in FIG. 8. It should be understood that there may be other plural intermetal dielectric layers above layer 73 that contain vias. The insulating layers 71, 73 may comprise any dielectric layer, such as at least one of silicon oxide, silicon nitride, silicon oxynitride, fluorinated silicon oxide, aluminum oxide, tantalum oxide, polymer material (such as HSQ for example), BPSG, PSG, BSG or spin on glass. In should be noted that the insulating layers 71, 73 may comprise plural sublayers of different dielectric materials, if desired.

The first level insulating layer 71 contains a first via 75 and a second via 77. The vias are formed using two masks according to the first, second or third preferred embodiments, as illustrated in FIGS. 3A-3E, 4A-4E or 5A-E. For example, via 75 may be formed using mask 29 and via 77 may be formed using mask 30. Of course, adjacent vias formed using two masks may be located in locations other than on either side of a gate electrode of a MOSFET. Conductive electrodes 79 are formed in the vias 75 and 77. The vias 75, 77 extend to the active device 63, such that the electrodes 79 contact the source and drain regions 65. The electrode material may be selected from at least one of polysilicon, aluminum, copper, tungsten, titanium, titanium nitride or metal silicide.

The first intermetal dielectric layer 73 contains a first via 85 and a second via 87. The vias are formed using two masks, as illustrated in FIGS. 3A-3E, 4A-4E or 5A-E. For example, via 85 may be formed using mask 29 and via 87 may be formed using mask 30. Conductive first level interconnect metallization layers 89 are formed in the vias 85 and 87. The vias 85, 87 extend to the electrodes 79, such that the metallization layers 89 contact the electrodes 79. The metallization 89 material may be selected from at least one of polysilicon, aluminum, copper, tungsten, titanium, titanium nitride or metal silicide. A second level intermetal dielectric layer 91 overlies metallization layer 89.

Thus, the first via 75, 85 and a second via 77, 87 in the insulating layers 71, 73 made by two mask lithography, are separated by a reproducible distance 39 that is smaller than a distance 19 that may be reproducibly achieved by forming the first and the second via using one mask photolithography. Preferably, the first via 75, 85 and the second via 77, 87 are separated by a distance of 0.17 microns or less, more preferably between 0.07 and 0.12 microns, most preferably between 0.07 and 0.08 microns.

Thus, the method of the preferred embodiments of the present invention provides more space to size the vias than the prior art process. This improves the error margin in the photolithography process and improves the definition between the bright and dark fields. The method of the preferred embodiments of the present invention also allows fabrication of masks or reticles with larger features, which simplifies mask or reticle fabrication. Furthermore, a rectangular rather than oval cross sectional via shape may be obtained.

While the invention has been described in detail and with reference to specific embodiments thereof, it will be apparent to one skilled in the art that various changes and modifications can be made therein without departing from the scope of the invention. Thus, the breadth and scope of the present invention should not be limited by any of the above-described exemplary embodiments, but should be defined only in accordance with the following claims and their equivalents.

1. A method of making plurality of vias in a first layer, comprising:
forming a first photoresist layer over the first layer;
exposing the first photoresist layer through a first mask;
forming a first opening in the first photoresist layer;
forming a first via in the first layer through the first opening in the first photoresist layer;
forming a second photoresist layer, different from the first photoresist layer, over the first layer;
exposing the second photoresist layer through a second mask different from the first mask;
forming a second opening in the second photoresist layer; and
forming a second via in the first layer through the second opening in the second photoresist layer.

2. The method of claim 1, further comprising removing the first photoresist layer after the step of forming the first via and before the step of forming the second photoresist layer.

3. The method of claim 2, wherein:
the step of forming the first via comprises providing an etching gas or an etching liquid to the first layer through the first opening in the first photoresist layer; and
the step of forming the second via comprises providing an etching gas or an etching liquid to the first layer through the second opening in the second photoresist layer.

4. The method of claim 3, wherein:
the step of exposing the first photoresist layer through the first mask comprises exposing a first region of the first photoresist layer to radiation through the first mask; and
the step of exposing the second photoresist layer through the second mask comprises exposing a second region of the second photoresist layer to radiation through the second mask.

5. The method of claim 4, wherein:
the step of forming the first opening in the first photoresist layer comprises removing the exposed first region of the first photoresist layer; and
the step of forming the second opening in the second photoresist layer comprises removing the exposed second region of the second photoresist layer.

6. The method of claim 4, wherein:
the step of forming the first opening in the first photoresist layer comprises removing an unexposed region of the first photoresist layer without removing the exposed first region of the first photoresist layer; and
the step of forming the second opening in the second photoresist layer comprises removing an unexposed region of the second photoresist layer without removing the exposed second region of the second photoresist layer.

7. The method of claim 4, wherein the first layer comprises an insulating layer.

8. The method of claim 7, further comprising:
forming a first set of a plurality of vias in the insulating layer using the first mask; and
forming a second set of a plurality of vias in the insulating layer using the second mask.

9. The method of claim 8, wherein:
the vias of the first and the second sets are arranged in a square matrix;
a shortest distance between adjacent vias of the same set is a diagonal line with respect to the square matrix;
the first via is located between at least two vias from the second set; and
the second via is located between at least two vias from the first set.

10. The method of claim 7, wherein the first via and the second via are separated by a distance that is smaller than a distance that may be reproducibly achieved by forming the first and the second via using the same mask.

11. The method of claim 10, wherein the first via and the second via are separated by a distance that is less than the wavelength of the exposing radiation but is equal to or greater than about ½ of the wavelength of the exposing radiation.

12. The method of claim 1, further comprising:
forming at least one semiconductor device on a substrate;
forming the first layer comprising an insulating material over the semiconductor device; and
forming a conductive material in the first and the second vias.

13. The method of claim 12, wherein:
the substrate comprises a semiconductor, a glass or a plastic material;
the first layer comprises at least one of silicon oxide, silicon nitride, silicon oxynitride, fluorinated silicon oxide, aluminum oxide, tantalum oxide, BPSG, PSG, BSG, polymer material or spin on glass;
the conductive material comprises an electrode or an interconnect metallization selected from at least one of polysilicon, aluminum, copper, tungsten, titanium, titanium nitride or metal silicide;
the at least one semiconductor device comprises at least one of a MOSFET, a MESFET, a bipolar transistor, a capacitor or a resistor; and
the first and the second vias extend to the at least one semiconductor device or to a conductive layer above the semiconductor device.

14. The method of claim 12, wherein the first via and the second via are separated by 0.17 microns or less.

15. The method of claim 14, wherein the first via and the second via are separated by 0.07 to 0.12 microns.

16. The method of claim 15, wherein the first via and the second via are separated by 0.07 to 0.08 microns

17. A semiconductor device made by the method of claim 12.

18. A method of making plurality of vias in a first layer, comprising:
forming a first photoresist layer over an hard mask layer which is located above the first layer;
exposing the first photoresist layer through a first mask;
forming a first opening in the first photoresist layer;
forming a first opening in the hard mask layer through the first opening in the first photoresist layer;
forming a second photoresist layer, different from the first photoresist layer, over the hard mask layer;
exposing the second photoresist layer through a second mask different from the first mask;
forming a second opening in the second photoresist layer;
forming a second opening in the hard mask layer through the second opening in the second photoresist layer; and
forming a first via and a second via in the first layer using the hard mask layer as a mask.

19. The method of claim 18, further comprising:
removing the first photoresist layer before forming the second photoresist layer; and
removing the second photoresist layer before forming the first and the second vias.

20. The method of claim 19, wherein:
the step of forming the first opening in the hard mask layer comprises providing a first etching gas or liquid to the hard mask layer through the first opening in the photoresist layer;
the step of forming the second opening in the hard mask layer comprises providing the first etching gas or liquid to the hard mask layer through the second opening in the photoresist layer; and
the step of forming the first and the second vias comprises providing a second etching gas or liquid to the first layer through the first and the second openings in the hard mask layer.

21. The method of claim 20, wherein:
the step of exposing the photoresist layer through the first mask comprises exposing a first region of the photoresist layer to radiation;
the step of exposing the photoresist layer through the second mask comprises exposing a second region of the photoresist layer to radiation.
the step of forming the first opening in the photoresist layer comprises removing the exposed first region of the photoresist layer; and
the step of forming the second opening in the photoresist layer comprises removing the exposed second region of the photoresist layer.

22. The method of claim 18, wherein the first layer comprises an insulating layer.

23. The method of claim 22, further comprising:
forming a first set of a plurality of vias in the insulating layer using the first mask; and
forming a second set of a plurality of vias in the insulating layer using the second mask.

24. The method of claim 23, wherein:
the vias of the first and the second sets are arranged in a square matrix;
a shortest distance between adjacent vias of the same set is a diagonal line with respect to the square matrix;
the first via is located between at least two vias from the second set; and
the second via is located between at least two vias from the first set.

25. The method of claim 22, wherein the first via and the second via are separated by a distance that is smaller than a distance that may be reproducibly achieved by forming the first and the second via using the same mask.

26. The method of claim 25, wherein the first via and the second via are separated by a distance that is less than the wavelength of the exposing radiation but is equal to or greater than about ½ of the wavelength of the exposing radiation.

27. The method of claim 22, further comprising:
forming at least one semiconductor device on a substrate;
forming the first insulating layer over the semiconductor device; and
forming a conductive material in the first and second vias.

28. The method of claim 27, wherein:
the substrate comprises a semiconductor, a glass or a plastic material;
the first insulating layer comprises at least one of silicon oxide, fluorinated silicon oxide, BPSG, PSG, BSG, polymer material or spin on glass; the hard mask layer comprises silicon nitride, silicon oxynitride, aluminum oxide or tantalum oxide;
the conductive material comprises an electrode or an interconnect metallization selected from at least one of polysilicon, aluminum, copper, tungsten, titanium, titanium nitride or metal silicide;
the at least one semiconductor device comprises at least one of a MOSFET, a MESFET, a bipolar transistor, a capacitor or a resistor; and
the first and the second vias extend to the at least one semiconductor device or to a third conductive layer above the semiconductor device.

29. The method of claim 27, wherein the first via and the second via are separated by 0.17 microns or less.

30. The method of claim 29, wherein the first via and the second via are separated by 0.07 to 0.12 microns.

31. The method of claim 30, wherein the first via and the second via are separated by 0.07 to 0.08 microns.

32. A semiconductor device made by the method of claim 27.

33. A semiconductor device, comprising:
an active element on a substrate;
an insulating layer over the active element;
a first via and a second via in the insulating layer which are separated by a distance of 0.17 microns or less; and
a conductive material in the first and second vias.

34. The device of claim 33, wherein the first via and the second via are separated by 0.07 to 0.12 microns.

35. The device of claim 34, wherein the first via and the second via are separated by 0.07 to 0.08 microns.

36. The device of claim 33, further comprising:
a first set of a plurality of first vias in the insulating layer;
a second set of a plurality of second vias in the insulating layer; wherein:
the first via is located between at least two second vias from the second set;
the second via is located between at least two first vias from the first set; and
each second via is separated by 0.17 microns or less from at least one first via.

37. The device of claim 36, wherein:
the vias of the first and the second sets are arranged in a square matrix; and
a shortest distance between adjacent vias of the same set is a diagonal line with respect to the square matrix.

38. The device of claim 33, wherein the conductive material comprises an electrode or interconnect metallization.

39. The device of claim 38, wherein:
the substrate comprises a semiconductor, a glass or a plastic material;
the insulating layer comprises at least one of silicon oxide, silicon nitride, silicon oxynitride, fluorinated silicon oxide, aluminum oxide, tantalum oxide, BPSG, PSG, BSG, polymer material or spin on glass;
the conductive material comprises least one of polysilicon, aluminum, copper, tungsten, titanium, titanium nitride or metal silicide; and
the active element comprises at least one of a MOSFET, a MESFET, a bipolar transistor, a capacitor or a resistor.
